(19) United States
(12) Patent Application Publication
(10) Pub. No.: US 2026/0211178 A1
(43) Pub. Date: Jul. 23, 2026

(54) SEMICONDUCTOR PACKAGE

(71) Applicant: SAMSUNG ELECTRONICS CO., LTD., Suwon-si (KR)

(72) Inventors: Nakyeong EOM, Suwon-si (KR); Geundo PARK, Suwon-si (KR)

(73) Assignee: SAMSUNG ELECTRONICS CO., LTD., Suwon-si (KR)

(21) Appl. No.: 19/291,944

(22) Filed: Aug. 6, 2025

(30) Foreign Application Priority Data
Jan. 20, 2025 (KR) 10-2025-0007907

(51) Int. Cl. G02B 6/12; H01L 25/16

(52) U.S. Cl. CPC G02B 6/12004; H10W 90/00

(57) ABSTRACT

A semiconductor package may include a package substrate and an optical structure disposed on the package substrate. The optical structure may include a photonic integrated circuit, a transfer structure, and a connection structure stacked in a first direction perpendicular to a top surface of the package substrate. The transfer structure may include a waveguide, and the connection structure may include an optical fiber. The optical fiber may include an inner core and a cladding structure enclosing the inner core. The waveguide and the optical fiber may extend in the first direction, and the waveguide and the inner core may be connected to each other.

### CROSS-REFERENCE TO RELATED APPLICATIONS

This U.S. non-provisional patent application claims priority under 35 U.S.C. § 119 to Korean Patent Application No. 10-2025-0007907, filed on Jan. 20, 2025, in the Korean Intellectual Property Office, the entire contents of which are hereby incorporated by reference.

### BACKGROUND OF THE INVENTION

The present disclosure relates to a semiconductor package, and in particular, to a semiconductor package including an optical structure.

The demand for miniaturization and high-speed performance in electronic devices is increasing. Accordingly, research is actively being conducted to replace conventional metal-based signal via patterns with an optical signal-based method. Thus, a semiconductor package, which includes a photonic integrated circuit with a light source or an optical coupling device, is needed to transfer optical signals.

### SUMMARY

An embodiment of the inventive concept provides a semiconductor package with improved optical characteristics.

According to an embodiment of the inventive concept, a semiconductor package may include a package substrate and an optical structure disposed on the package substrate. The optical structure may include a photonic integrated circuit, a transfer structure, and a connection structure stacked in a first direction perpendicular to a top surface of the package substrate. The transfer structure may include a waveguide, and the connection structure may include an optical fiber. The optical fiber may include an inner core and a cladding structure enclosing the inner core. The waveguide and the optical fiber may extend in the first direction, and the waveguide and the inner core may be connected to each other.

According to an embodiment of the inventive concept, a semiconductor package may include a package substrate, a photonic integrated circuit disposed on the package substrate, and an electronic integrated circuit, a transfer structure, and a connection structure disposed on the photonic integrated circuit. The electronic integrated circuit may be spaced apart from the transfer structure and the connection structure in a horizontal direction, and the transfer structure may be disposed between the photonic integrated circuit and the connection structure. The transfer structure may include a waveguide, and the connection structure may include an optical fiber. The optical fiber may include an inner core and a cladding structure enclosing the inner core, and the waveguide and the inner core may be connected to each other. The waveguide may have a first diameter, and the inner core may have a second diameter. The first diameter may be substantially equal to the second diameter.

According to an embodiment of the inventive concept, a semiconductor package may include a package substrate, an interposer substrate disposed on the package substrate, a chip structure, a logic chip, and an optical structure, which are disposed on the interposer substrate and are spaced apart from each other in a first direction parallel to a top surface of the package substrate. The optical structure may include a photonic integrated circuit, an electronic integrated circuit disposed on the photonic integrated circuit, a transfer structure and a connection structure, which are disposed on the photonic integrated circuit and are spaced apart from the electronic integrated circuit in the first direction. The transfer structure may be disposed between the photonic integrated circuit and the connection structure, and the transfer structure may include a plurality of waveguides and a glass block enclosing the plurality of waveguides. The connection structure may include a plurality of optical fibers and a fastening structure enclosing the plurality of optical fibers. Each of the waveguides and the optical fibers may extend in a second direction perpendicular to the top surface of the package substrate. Each of the plurality of optical fibers may include an inner core and a cladding structure enclosing the inner core, and the plurality of waveguides may be respectively connected to the inner cores of the plurality of optical fibers.

### BRIEF DESCRIPTION OF THE DRAWINGS

FIG. 1 is a plan view illustrating a semiconductor package according to an embodiment of the inventive concept.

FIG. 2 is a sectional view taken along a line A-A′ of FIG. 1.

FIG. 3 is an enlarged sectional view illustrating a portion CU of FIG. 2.

FIG. 4A is a plan view illustrating a transfer structure according to an embodiment of the inventive concept.

FIG. 4B is a plan view illustrating a connection structure according to an embodiment of the inventive concept.

FIG. 5 is an enlarged sectional view illustrating a portion CU of FIG. 2, according to an embodiment of the inventive concept.

FIG. 6 is an enlarged sectional view illustrating a portion CU of FIG. 2, according to an embodiment of the inventive concept.

FIGS. 7, 8, 9, 10, and 11 are sectional views illustrating a process of fabricating a semiconductor package according to an embodiment of the inventive concept.

### DETAILED DESCRIPTION

Example embodiments of the inventive concepts will now be described more fully with reference to the accompanying drawings, in which example embodiments are shown.

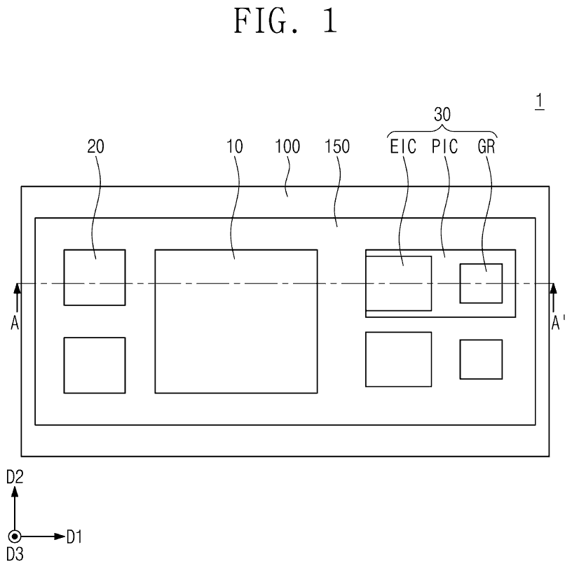

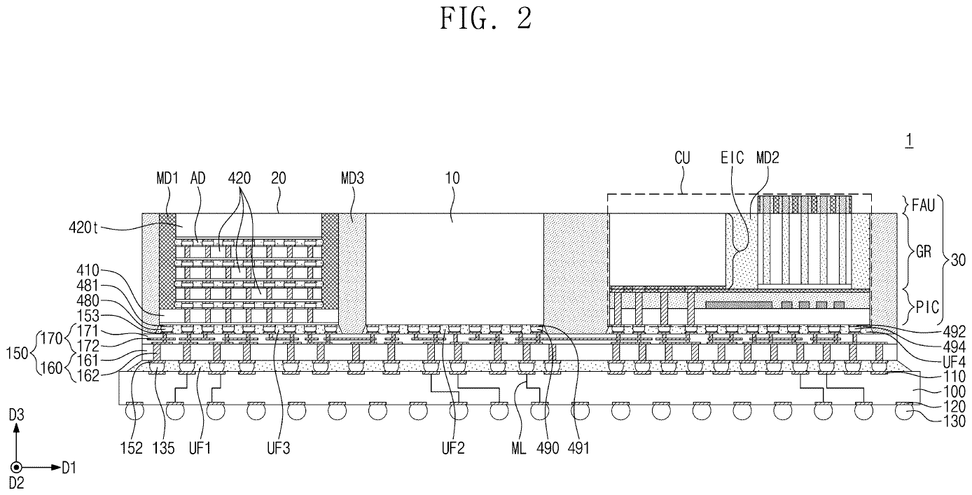

FIG. 1 is a plan view illustrating a semiconductor package according to an embodiment of the inventive concept. FIG. 2 is a sectional view taken along a line A-A′ of FIG. 1.

Referring to FIGS. 1 and 2, a semiconductor package 1 according to an embodiment of the inventive concept may include a package substrate 100, an interposer substrate 150, a first semiconductor chip 10, a chip structure 20, and an optical structure 30.

The package substrate 100 may be, for example, a printed circuit board (PCB). In addition, although not shown, the package substrate 100 may have a structure in which insulating layers and interconnection layers are alternately stacked. The package substrate 100 may include a plurality of first substrate pads 110, which are provided on a top surface thereof, and a plurality of second substrate pads 120 and a plurality of metal lines ML, which are placed on a bottom surface thereof.

Outer connection terminals 130 may be disposed on the second substrate pads 120, respectively. The outer connection terminals 130 may be electrically connected to an interconnection layer and the first substrate pads 110, which are placed in the package substrate 100, through the second substrate pads 120.

The outer connection terminals 130 may include solder balls or solder bumps. Depending on the kind or arrangement of outer connection terminals 130, the semiconductor package may have a ball grid array (BGA) structure, a fine ball-grid array (FBGA) structure, or a land grid array (LGA) structure. The outer connection terminal 130 may be formed of or include alloys containing at least one of silver, copper, or tin.

The interposer substrate 150 may be disposed on the package substrate 100. The interposer substrate 150 may include an interposer core layer 160 and an interposer interconnection layer 170. The interposer core layer 160 may include a core substrate 161 and interposer vias 162, which are provided to vertically penetrate the core substrate 161. The core substrate 161 may be a semiconductor substrate (e.g., a silicon (Si) substrate). In an embodiment, a plurality of interposer vias 162 may be arranged in a first direction D1.

In the present specification, the first direction D1 may be defined to be parallel to a top surface of the package substrate 100. A second direction D2 may be defined as a direction that is parallel to the top surface of the package substrate 100 and is perpendicular to the first direction D1. A third direction D3 may be defined to be perpendicular to the top surface of the package substrate 100.

The interposer interconnection layer 170 may be disposed on the interposer core layer 160. That is, the interposer core layer 160 may be disposed to be closer to the package substrate 100 to the interposer interconnection layer 170. The interposer interconnection layer 170 may include an interposer insulating layer 171 and interconnection patterns 172 in the interposer insulating layer 171. The interconnection patterns 172 may be electrically connected to the interposer vias 162. The interposer insulating layer 171 may be formed of or include at least one of insulating materials (e.g., silicon oxide and silicon nitride). The interconnection patterns 172 may be formed of or include at least one of metallic materials (e.g., copper).

Upper interposer pads 153 may be disposed on a top surface of the interposer substrate 150. Lower interposer pads 152 may be disposed on a bottom surface of the interposer substrate 150. The upper interposer pads 153 may be exposed through the top surface of the interposer substrate 150. The lower interposer pads 152 may be exposed through the bottom surface of the interposer substrate 150.

First connection terminals 135 may be disposed between the package substrate 100 and the interposer substrate 150. In detail, each of the first connection terminals 135 may be interposed between the lower interposer pads 152 and the first substrate pads 110 and may be in contact with them. The first connection terminals 135 may include a metallic material that is substantially the same as or similar to that of the outer connection terminal 130. For example, the first connection terminals 135 may be formed of or include alloys containing at least one of tin (Sn), silver (Ag), or copper (Cu).

A first under-fill layer UF1 may be provided between the package substrate 100 and the interposer substrate 150. The first under-fill layer UF1 may fill a space between the package substrate 100 and the interposer substrate 150 and may enclose a side surface of each of the first connection terminals 135. The first under-fill layer UF1 may be formed of or include, for example, an epoxy resin.

The first semiconductor chip 10 may be disposed on the interposer substrate 150. The first semiconductor chip 10 may include a graphics processing unit (GPU) die, a central processing unit (CPU) die, or a system-on-chip (SoC). In an embodiment, the first semiconductor chip 10 may be a logic chip.

First pads 491 may be disposed on a bottom surface of the first semiconductor chip 10. Second connection terminals 490 may be respectively disposed between the first semiconductor chip 10 and the interposer substrate 150. In detail, the second connection terminals 490 may be interposed between the first pads 491 and the upper interposer pads 153 and may be in contact with them. The first semiconductor chip 10 may be electrically connected to the package substrate 100 through the second connection terminals 490. The second connection terminals 490 may be formed of or include at least one of silver, copper, or tin.

A second under-fill layer UF2 may be provided between the first semiconductor chip 10 and the interposer substrate 150. The second under-fill layer UF2 may fill a space between the first semiconductor chip 10 and the interposer substrate 150 and may enclose a side surface of each of the second connection terminals 490. The second under-fill layer UF2 may be formed of or include, for example, an epoxy resin.

The chip structure 20 may be disposed on the interposer substrate 150. In the present specification, the chip structure 20 may be referred to as a chip stack 20 or a high bandwidth memory (HBM) 20. The chip structure 20 may include a second semiconductor chip 410 and third semiconductor chips 420 and 420t and a first mold layer MD1, which are disposed on the second semiconductor chip 410. In the present specification, the second semiconductor chip 410 may be referred to as a base chip 410, and the third semiconductor chips 420 and 420t may be referred to as the memory chips 420 and 420t.

The base chip 410 may be a logic chip. The base chip 410 may be a memory controller. The memory chips 420 and 420t may be stacked on the base chip 410 in the third direction D3. The memory chips 420 and 420t may be semiconductor chips that include the same circuit and are of the same kind. Each of the memory chips 420 and 420t may be one of DRAM or NAND FLASH chips.

Each of the base chip 410 and the memory chips 420 and 420t may include a circuit layer. The base chip 410 and the memory chips 420 may include penetration vias. The memory chip 420t, which is the uppermost one of the memory chips 420 and 420t, may not include the penetration vias. In an embodiment, the uppermost memory chip 420t may include penetration vias, unlike the illustrated example. The penetration vias of the base chip 410 may be connected to the penetration vias of the memory chip 420 adjacent thereto through micro-bumps. The penetration vias between the memory chips 420, which are adjacent to each other, may be connected to each other through micro-bumps.

Adhesive layers AD may be interposed between the base chip 410 and the memory chip 420, which are adjacent to each other, and between the memory chips 420, which are adjacent to each other. In an embodiment, the adhesive layers AD may be a non-conductive film (NCF) containing polymer.

A first mold layer MD1 may cover a top surface of the base chip 410, a side surface of the memory chips 420 and 420t, and side surfaces of the adhesive layers AD. A top surface of the uppermost memory chip 420t may be exposed from the first mold layer MD1. The first mold layer MD1 may be formed of or include an insulating material (e.g., epoxy molding compound (EMC)).

second pads 481 may be disposed on a bottom surface of the chip structure 20. Third connection terminals 480 may be respectively disposed between the chip structure 20 and the interposer substrate 150. In detail, the third connection terminals 480 may be interposed between the second pads 481 and the upper interposer pads 153 and may be in contact with them. The chip structure 20 may be electrically connected to the package substrate 100 through the third connection terminals 480. The third connection terminals 480 may be formed of or include at least one of silver, copper, or tin.

A third under-fill layer UF3 may be provided between the chip structure 20 and the interposer substrate 150. The third under-fill layer UF3 may fill a space between the chip structure 20 and the interposer substrate 150 and may enclose a side surface of each of the third connection terminals 480. The third under-fill layer UF3 may be formed of or include, for example, an epoxy resin.

The optical structure 30 may be disposed on the interposer substrate 150. The first semiconductor chip 10, the chip structure 20, and the optical structure 30 may be spaced apart from each other in the first direction D1.

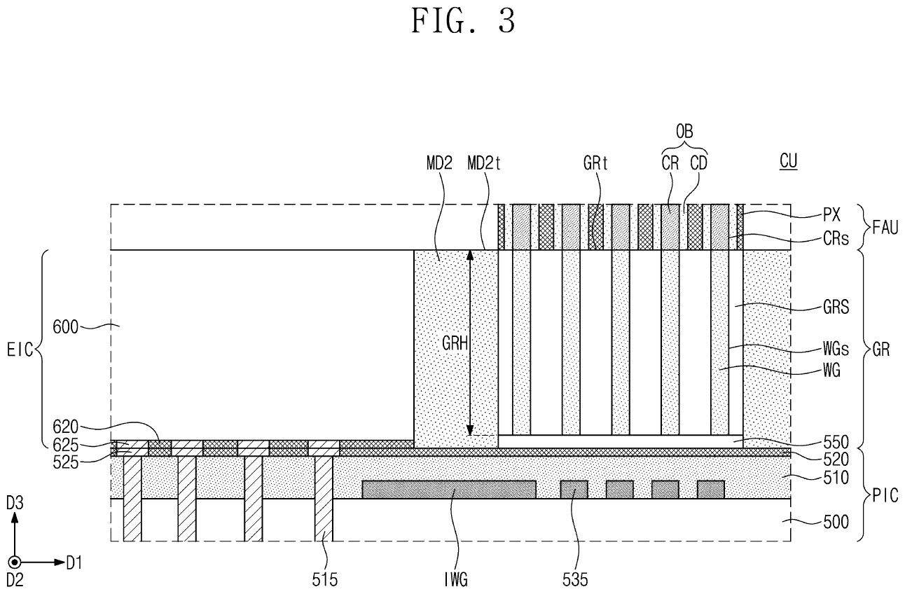

The optical structure 30 may include a photonic integrated circuit PIC and an electronic integrated circuit EIC, a transfer structure GR, and a connection structure FAU, which are provided on the photonic integrated circuit PIC. The electronic integrated circuit EIC may be spaced apart from the transfer structure GR and the connection structure FAU in the first direction D1. The transfer structure GR and the connection structure FAU may be stacked on the photonic integrated circuit PIC in the third direction D3. The transfer structure GR may be disposed between the photonic integrated circuit PIC and the connection structure FAU. The optical structure 30 will be described in more detail with reference to FIG. 3.

Third pads 492 may be disposed on a bottom surface of the optical structure 30. Fourth connection terminals 494 may be respectively disposed between the optical structure 30 and the interposer substrate 150. In detail, the fourth connection terminals 494 may be interposed between the third pads 492 and the upper interposer pads 153 and may be in contact with them. The optical structure 30 may be electrically connected to the package substrate 100 through the fourth connection terminals 494. The fourth connection terminals 494 may be formed of or include at least one of silver, copper, or tin.

A fourth under-fill layer UF4 may be provided between the optical structure 30 and the interposer substrate 150. The fourth under-fill layer UF4 may fill a space between the optical structure 30 and the interposer substrate 150 and may enclose a side surface of each of the fourth connection terminals 494. The fourth under-fill layer UF4 may be formed of or include, for example, epoxy resin.

A second mold layer MD2 may be provided to cover a top surface of the photonic integrated circuit PIC, a side surface of the electronic integrated circuit EIC, and a side surface of the transfer structure GR. The second mold layer MD2 may include an insulating material (e.g., epoxy molding compound (EMC)).

A third mold layer MD3 may be provided to cover a top surface of the interposer substrate 150, a side surface of the first semiconductor chip 10, a side surface of the first mold layer MD1, a side surface of the second mold layer MD2, and side surfaces of the second, third, and fourth under-fill layers UF2, UF3, and UF4. The third mold layer MD3 may be formed of or include at least one of insulating materials (e.g., epoxy molding compound (EMC)).

FIG. 3 is an enlarged sectional view illustrating a portion CU of FIG. 2. In detail, FIG. 3 is a sectional view illustrating the optical structure 30 of FIG. 2.

Referring to FIGS. 2 and 3, the optical structure 30 may include the photonic integrated circuit PIC, the electronic integrated circuit EIC, the transfer structure GR, and the connection structure FAU.

The photonic integrated circuit PIC may include a base layer 500, an optical path layer 510, a first junction layer 520, and vias 515. The base layer 500 may include a semiconductor substrate and a redistribution layer. The redistribution layer may include a plurality of interconnection lines.

The optical path layer 510 may be disposed on the base layer 500. The optical path layer 510 may include an inner waveguide IWG and couplers 535, which are disposed to be adjacent to an end portion of the inner waveguide IWG.

Light may be transmitted from the inner waveguide IWG to the couplers 535 or from the couplers 535 to the inner waveguide IWG. In an embodiment, the coupler 535 may be a grating coupler. For example, the coupler 535 may include diffraction patterns, which are formed near an end portion of the inner waveguide IWG and are configured to diffract light transmitted through the inner waveguide IWG, and such optical diffraction may be used to enable optical transceiving operations between the inner waveguide IWG and the couplers 535. The coupler 535 may include at least one of silicon (Si), silicon oxide (SiO₂), or silicon nitride (SiN). As an example, the coupler 535 may include a periodic array of silicon patterns. The inner waveguide IWG may be formed of or include at least one of silicon nitride (SiN) or silicon oxide (SiO₂).

Although not shown, optical devices with various functions may be disposed in the optical path layer 510. For example, the optical devices may include a semiconductor laser device, a light source, an optical amplifier, an electric signal amplifier, an optical modulator or a photodetector. The optical devices may be used as transceivers, either receiving external light, which will be transmitted to the photonic integrated circuit PIC, or emitting light from the photonic integrated circuit PIC to the outside. In an embodiment, at least one of the optical devices may be configured to convert light, which is transmitted through the inner waveguide IWG, to current signals.

Vias 515 may be disposed to penetrate the base layer 500 and the optical path layer 510. The vias 515 may be spaced apart from each other in the first direction D1. The first junction layer 520 may be disposed on the optical path layer 510. First connection pads 525 may be provided in the first junction layer 520. The first connection pads 525 may be connected to the vias 515. The first junction layer 520 may be formed of or include silicon carbon nitride (SiCN).

The electronic integrated circuit EIC may be disposed on the photonic integrated circuit PIC. The electronic integrated circuit EIC may include an electronic circuit layer 600 and a second junction layer 620 on a bottom surface of the electronic circuit layer 600. The electronic circuit layer 600 may include a semiconductor substrate and a redistribution layer. Second connection pads 625 may be provided in the second junction layer 620. The second connection pads 625 may be in contact with the first connection pads 525. The second junction layer 620 may be formed of or include silicon carbon nitride (SiCN). The electronic integrated circuit EIC may be electrically connected to the photonic integrated circuit PIC through a first connection pad PD1 and second connection pads PD2. The electronic integrated circuit EIC may be configured to transmit and receive electrical signals to and from the photonic integrated circuit PIC. As an example, the electronic integrated circuit EIC may be configured to convert current signals, which are transmitted from the optical path layer 510, to voltages and to amplify the voltages.

The transfer structure GR and the connection structure FAU may be disposed on the photonic integrated circuit PIC. The transfer structure GR and the connection structure FAU may be spaced apart from the electronic integrated circuit EIC in the first direction D1.

The transfer structure GR may include a plurality of waveguides WG and a glass block GRS enclosing the waveguides WG. The waveguides WG may be extended in the third direction D3. In an embodiment, although not shown, the waveguides WG may have a tapered shape.

A height GRH of the transfer structure GR may range from 400 μm to 900 μm. The height GRH of the transfer structure GR may correspond to the height of the waveguides WG. The waveguides WG may be formed of or include at least one of silicon nitride (SiN) or silicon oxide (SiO₂). The glass block GRS may be formed of or include glass. In this case, it may be possible to reduce the difference in thermal expansion coefficient between the glass block GRS and the waveguides WG, to improve the thermal resistance and thermal stress characteristics, and to improve the moldability of the transfer structure GR.

An adhesive member 550 may be disposed between the transfer structure GR and the photonic integrated circuit PIC. The adhesive member 550 may be optically transparent. In an embodiment, the adhesive member 550 may be formed of or include at least one of epoxy resin or acrylate.

The connection structure FAU may be disposed on the transfer structure GR. The transfer structure GR may be disposed between the photonic integrated circuit PIC and the connection structure FAU. In other words, the photonic integrated circuit PIC, the transfer structure GR, and the connection structure FAU may be stacked in the third direction D3. Thus, even when the waveguides WG and optical fibers OB to be described below are provided in plurality, it may be possible to easily couple the transfer structure GR to the connection structure FAU, on the photonic integrated circuit PIC. In addition, since the photonic integrated circuit PIC, the transfer structure GR, and the connection structure FAU are vertically stacked, the area of the interposer substrate may not be increased, and the production yield of the semiconductor package may be increased.

The connection structure FAU may include a plurality of the optical fibers OB, each of which includes an inner core CR and a cladding structure CD enclosing the inner core CR, and a fastening structure PX, which is configured to fasten the optical fibers OB. A top surface of the glass block GRS may be in contact with a bottom surface of the fastening structure PX. The cladding structure CD may be formed of or include fluorine-doped silicon oxide (SiO₂).

The optical fibers OB may be extended in the third direction D3. Here, each of the waveguides WG provided in the transfer structure GR may be respectively connected to the inner cores CR in the optical fibers OB. As an example, the side surface WGs of each of the waveguides WG may be aligned to a side surface CRs of each of the inner cores CR. The coupler 535, the waveguide WG, and the inner core CR of the optical fiber OB may be overlapped with each other in the third direction D3. Although not shown, the connection structure FAU may be connected to an external optical device. In this case, light may be transferred from the inner core CR of the optical fiber OB of the connection structure FAU through the waveguide WG of the transfer structure GR, the coupler 535, and the inner waveguide IWG.

The second mold layer MD2 may be provided on a top surface of the photonic integrated circuit PIC. The second mold layer MD2 may cover a side surface of the electronic integrated circuit EIC and a side surface of the transfer structure GR. A top surface MD2t of the second mold layer MD2 may be placed at the same level as a top surface GRt of the transfer structure GR.

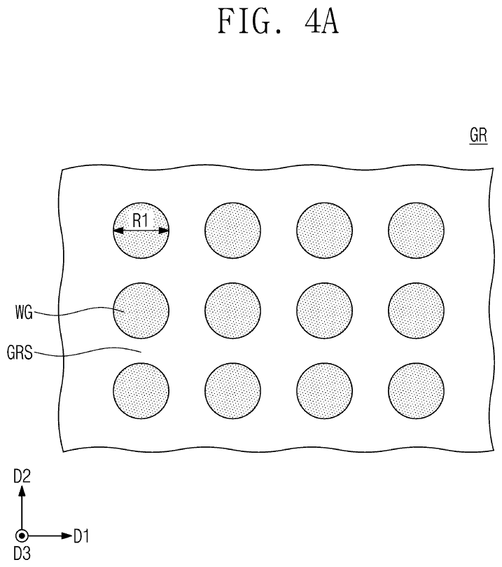

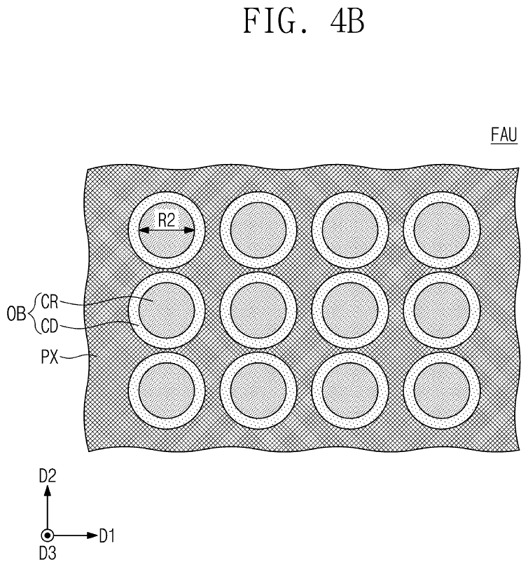

FIG. 4A is a plan view illustrating a transfer structure according to an embodiment of the inventive concept. FIG. 4B is a plan view illustrating a connection structure according to an embodiment of the inventive concept.

Referring to FIGS. 3, 4A, and 4B, the waveguides WG of the transfer structure GR may be provided in plurality, along the first and second directions D1 and D2. Each of the waveguides WG may have a first diameter R1.

The optical fibers OB of the connection structure FAU may be arranged in the first and second directions D1 and D2. The inner core CR of each of the optical fibers OB may have a second diameter R2. The first diameter R1 may be substantially equal to the second diameter R2. In an embodiment, the first and second diameters R1 and R2 may range from 8 μm to 10 μm. Since the first and second diameters R1 and R2 are equal to each other, the waveguide WG and the inner core CR of the optical fiber OB may be connected to each other, thereby forming a single object.

As used herein, the expression “substantially equal” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

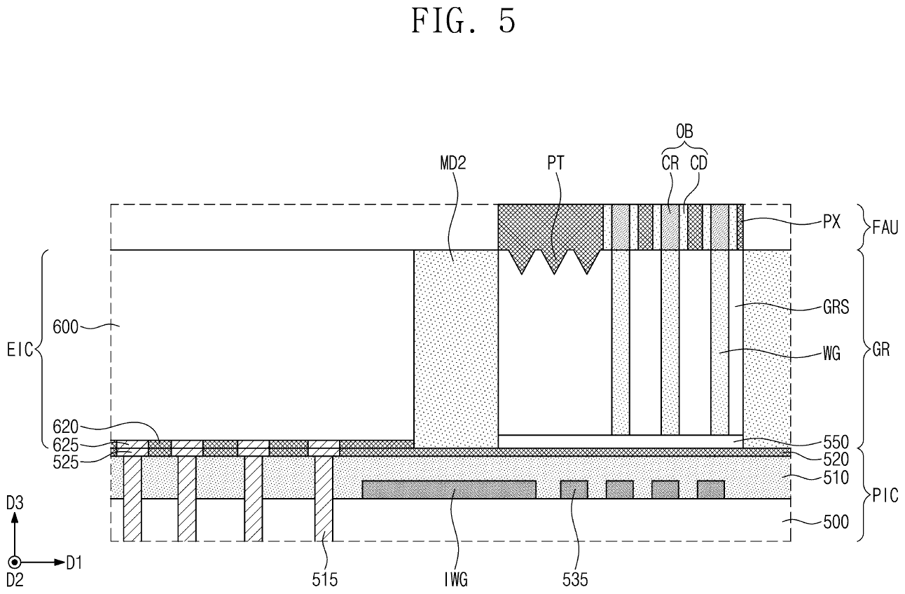

FIG. 5 is an enlarged sectional view illustrating a portion CU of FIG. 2, according to an embodiment of the inventive concept. For concise description, an element previously described with reference to FIG. 3 may be identified by the same reference number without repeating an overlapping description thereof.

Referring to FIG. 5, the fastening structure PX of the connection structure FAU may include a protruding portion PT placed near a bottom surface thereof. In an embodiment, a plurality of protruding portions PT may be provided. The protruding portion PT and the waveguide WG may be vertically overlapped with each other. The connection structure FAU and the transfer structure GR may be coupled to each other through the protruding portion PT.

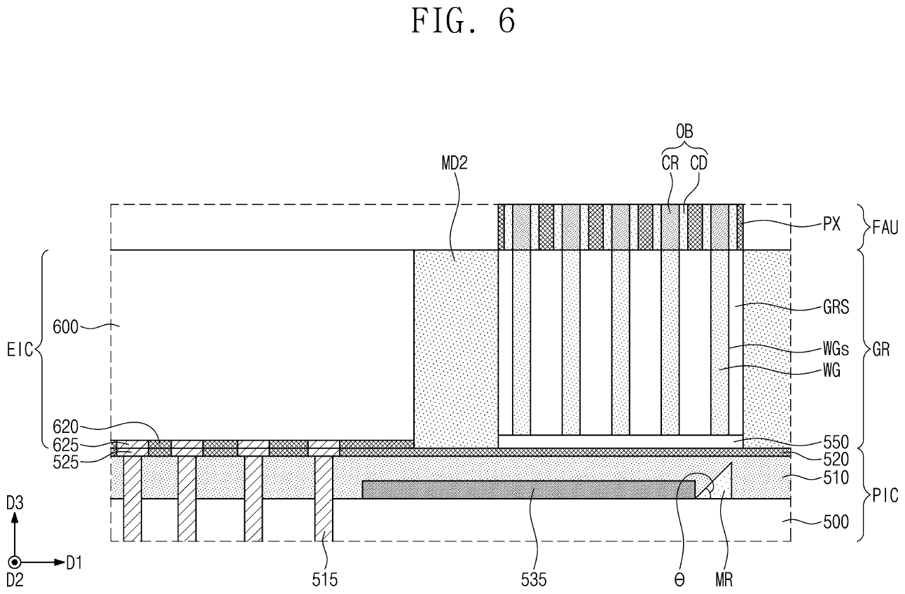

FIG. 6 is an enlarged sectional view illustrating a portion CU of FIG. 2, according to an embodiment of the inventive concept. For concise description, an element previously described with reference to FIG. 3 may be identified by the same reference number without repeating an overlapping description thereof.

Referring to FIG. 6, the photonic integrated circuit PIC may include a reflecting member MR. An angle θ of the reflecting member MR may be about 45°. The reflecting member MR may include, for example, a mirror. Here, the coupler 535 may have a structure extending in the first direction D1. Light transmitted from the waveguide WG may be reflected by the reflecting member MR and may be transmitted to the coupler 535.

In an embodiment, the semiconductor package may include a transfer structure and a connection structure, which are vertically stacked on the photonic integrated circuit. Here, the transfer structure and the connection structure may include a plurality of waveguides and a plurality of optical fibers, respectively, and inner cores of the waveguide and the optical fiber may be connected to each other, thereby forming a single object. Thus, light may be transmitted from the optical fibers to the waveguides, without an optical loss issue. As a result, the optical characteristics of the semiconductor package may be improved.

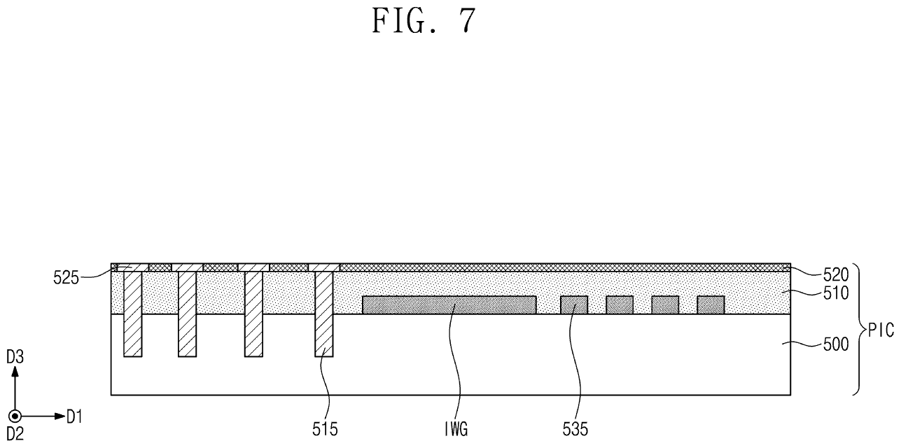

FIGS. 7, 8, 9, 10, and 11 are sectional views illustrating a process of fabricating a semiconductor package according to an embodiment of the inventive concept.

Referring to FIG. 7, the photonic integrated circuit PIC may be provided. The photonic integrated circuit PIC may include the base layer 500, the optical path layer 510, the first junction layer 520, and the vias 515. The optical path layer 510 may include the inner waveguide IWG and the couplers 535, which are provided near an end portion of the inner waveguide IWG. The first junction layer 520 may include the first connection pads 525. Here, a height of the vias 515 may be smaller than a sum of a thickness of the base layer 500 and a thickness of the optical path layer 510.

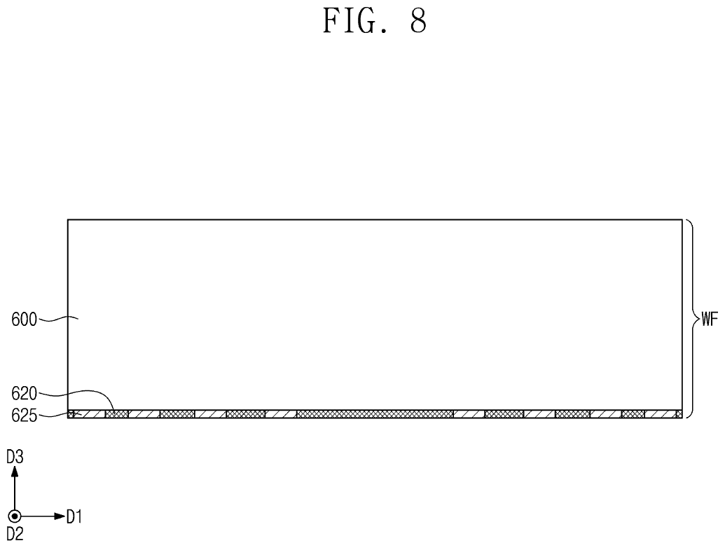

Referring to FIG. 8, a wafer WF may be provided. The wafer WF may include regions, on which the electronic integrated circuit EIC described with reference to FIG. 3 are formed. In detail, the wafer WF may include the electronic circuit layer 600 and the second junction layer 620, which is provided on the bottom surface of the electronic circuit layer 600. The electronic circuit layer 600 may include a semiconductor substrate and a redistribution layer. The second connection pads 625 may be provided in the second junction layer 620.

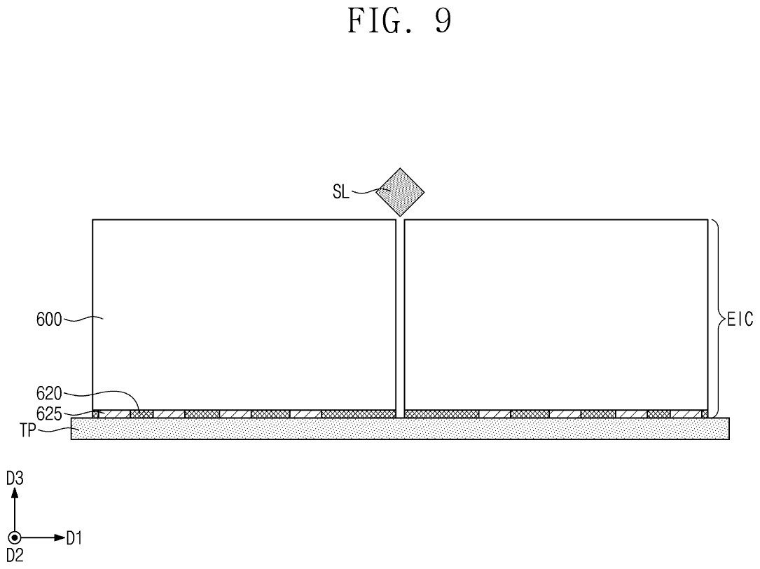

Referring to FIG. 9, a tape TP may be provided on a bottom surface of the wafer WF. Next, a sawing process may be performed on the wafer WF. The sawing process may be executed using, for example, a sawing blade SL. As a result of the sawing process, a plurality of electronic integrated circuits EIC may be formed from the wafer WF.

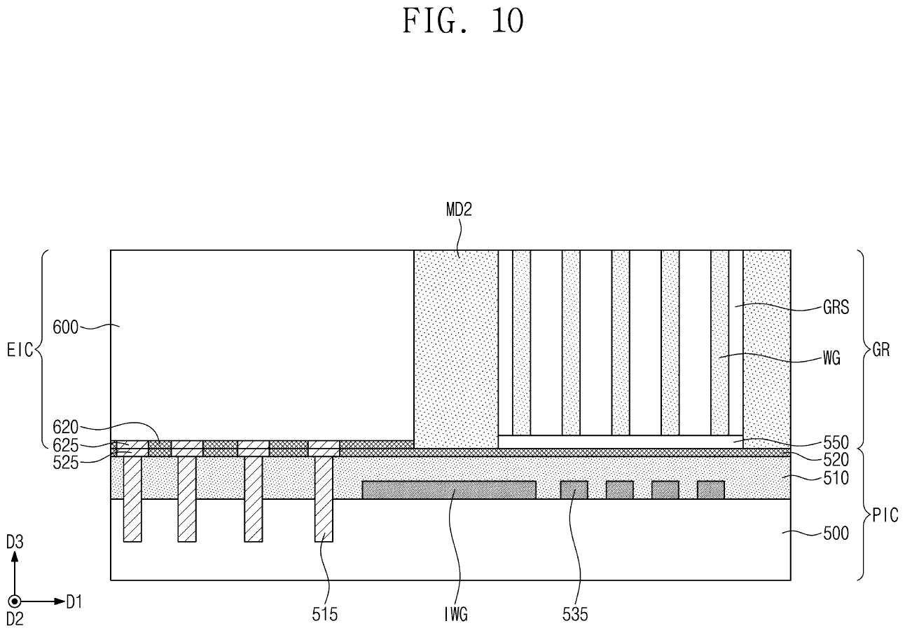

Referring to FIG. 10, the electronic integrated circuit EIC of FIG. 9 may be placed on and connected to the photonic integrated circuit PIC. In detail, the first connection pad 525 of the photonic integrated circuit PIC may be bonded to the second connection pad 625 of the electronic integrated circuit EIC.

The transfer structure GR may be placed on and coupled to the photonic integrated circuit PIC. The transfer structure GR may include the waveguides WG and the glass block GRS enclosing the waveguides WG. The adhesive member 550 may be provided for the coupling between the transfer structure GR and the photonic integrated circuit PIC.

Next, the second mold layer MD2 may be formed on a top surface of the photonic integrated circuit PIC. The second mold layer MD2 may enclose a side surface of the electronic integrated circuit EIC and a side surface of the transfer structure GR. Here, a top surface of the second mold layer MD2 may be placed at substantially the same level as a top surface of the electronic integrated circuit EIC and a top surface of the transfer structure GR.

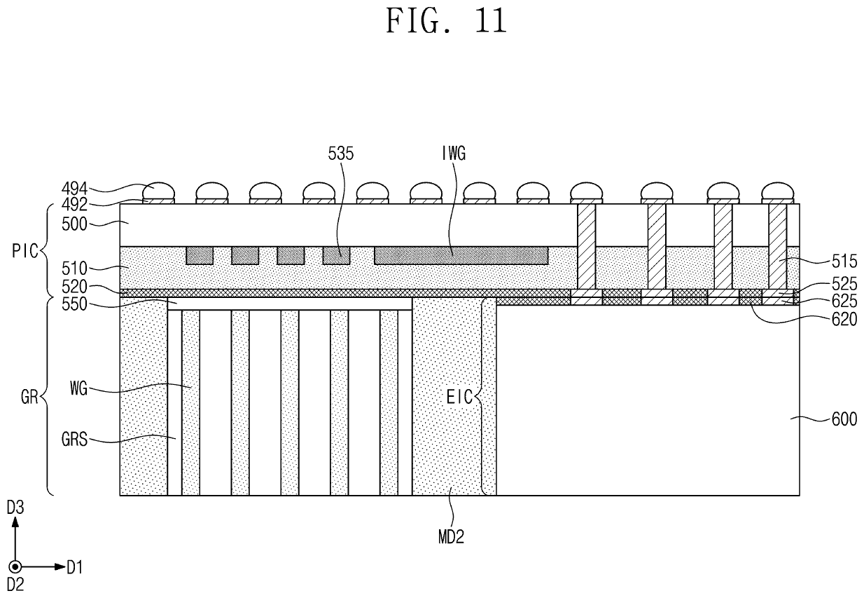

Referring to FIG. 11, the photonic integrated circuit PIC, the electronic integrated circuit EIC, and the transfer structure GR may be inverted. A grinding process may be performed on a bottom surface of the base layer 500, which is included in the photonic integrated circuit PIC. The grinding process may be performed to expose bottom surfaces of the vias 515. As a result of the grinding process, a thickness of the base layer 500 in the third direction D3 may be reduced, and as a result, the optical structure 30 described with reference to FIG. 2 may be formed.

The third pads 492 may be formed on the bottom surface of the base layer 500, and the fourth connection terminals 494 may be formed on the third pads 492. The photonic integrated circuit PIC, the electronic integrated circuit EIC, and the transfer structure GR may be inverted.

Next, referring back to FIG. 2, the interposer substrate 150 may be mounted on the package substrate 100, and the first semiconductor chip 10, the chip structure 20, and the optical structure 30 may be mounted on the top surface of the interposer substrate 150. The third mold layer MD3 may be formed on the top surface of the interposer substrate 150, and the outer connection terminals 130 may be attached to the second substrate pads 120, which are placed on a bottom surface of the package substrate 100. As a result, the semiconductor package 1 may be fabricated.

According to an embodiment of the inventive concept, a semiconductor package may include a transfer structure and a connection structure, which are vertically stacked on a photonic integrated circuit. Here, the transfer structure and connection structure may include a plurality of waveguides and a plurality of optical fibers, respectively, and inner cores of the waveguides and the optical fibers may be connected to each other, thereby forming a single object. Thus, light may be transmitted from the optical fibers to the waveguides, without an optical loss issue. As a result, the optical characteristics of the semiconductor package may be improved.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a package substrate; and
an optical structure disposed on the package substrate,
wherein the optical structure includes a photonic integrated circuit, a transfer structure, and a connection structure stacked in a first direction perpendicular to a top surface of the package substrate,
the transfer structure includes a waveguide,
the connection structure includes an optical fiber, and
the optical fiber includes an inner core and a cladding structure enclosing the inner core,
the waveguide and the optical fiber extend in the first direction, and
the waveguide and the inner core are connected to each other.

2. The semiconductor package of claim 1, wherein the transfer structure includes a glass block enclosing the waveguide.

3. The semiconductor package of claim 1, wherein a height of the transfer structure ranges from 400 μm to 900 μm.

4. The semiconductor package of claim 1, wherein a side surface of the waveguide is aligned to a side surface of the inner core of the optical fiber.

5. The semiconductor package of claim 1, further comprising an adhesive member disposed between the photonic integrated circuit and the transfer structure,
wherein the adhesive member includes at least one of epoxy resins or acrylate.

6. The semiconductor package of claim 1, wherein the photonic integrated circuit includes a coupler,
wherein the coupler overlaps the waveguide and the optical fiber in the first direction.

7. The semiconductor package of claim 1, wherein the optical structure further includes an electronic integrated circuit disposed on the photonic integrated circuit, and
the electronic integrated circuit is spaced apart from the transfer structure and the connection structure in a second direction parallel to the top surface of the package substrate.

8. The semiconductor package of claim 1, wherein the waveguide and the optical fiber are provided in plurality in the transfer structure and the connection structure, respectively.

9. A semiconductor package, comprising:
a package substrate;
a photonic integrated circuit disposed on the package substrate; and
an electronic integrated circuit, a transfer structure, and a connection structure disposed on the photonic integrated circuit,
wherein the electronic integrated circuit is spaced apart from the transfer structure and the connection structure in a horizontal direction,
the transfer structure is disposed between the photonic integrated circuit and the connection structure,
the transfer structure includes a waveguide,
the connection structure includes an optical fiber,
the optical fiber includes an inner core and a cladding structure enclosing the inner core,
the waveguide and the inner core are connected to each other,
the waveguide has a first diameter,
the inner core has a second diameter, and
the first diameter is substantially equal to the second diameter.

10. The semiconductor package of claim 9, wherein the first diameter and the second diameter each range from 8 μm to 10 μm.

11. The semiconductor package of claim 9, wherein the connection structure includes a fastening structure enclosing the optical fiber,
the fastening structure includes a protruding portion placed near a bottom surface thereof, and
the transfer structure and the connection structure are coupled to each other through the protruding portion.

12. The semiconductor package of claim 9, wherein the photonic integrated circuit includes a coupler and a reflecting member,
the reflecting member is disposed to be adjacent to an end portion of the coupler, and
the reflecting member is placed at an angle of 45°.

13. The semiconductor package of claim 9, further comprising a mold layer disposed on a top surface of the photonic integrated circuit,
wherein a top surface of the mold layer is placed at substantially the same level as a top surface of the transfer structure.

14. The semiconductor package of claim 9, wherein the photonic integrated circuit includes an inner waveguide and a coupler, and
the coupler is disposed to be adjacent to an end portion of the inner waveguide.

15. A semiconductor package, comprising:
a package substrate;
an interposer substrate disposed on the package substrate;
a chip structure, a logic chip, and an optical structure, which are disposed on the interposer substrate and are spaced apart from each other in a first direction parallel to a top surface of the package substrate,
wherein the optical structure includes:
a photonic integrated circuit;
an electronic integrated circuit disposed on the photonic integrated circuit; and
a transfer structure and a connection structure, which are disposed on the photonic integrated circuit and are spaced apart from the electronic integrated circuit in the first direction,
wherein the transfer structure is disposed between the photonic integrated circuit and the connection structure,
the transfer structure includes a plurality of waveguides and a glass block enclosing the plurality of waveguides,
the connection structure includes a plurality of optical fibers and a fastening structure enclosing the plurality of optical fibers,
each of the waveguides and the optical fibers extends in a second direction perpendicular to the top surface of the package substrate,
each of the plurality of optical fibers includes an inner core and a cladding structure enclosing the inner core, and
the plurality of waveguides is respectively connected to the inner cores of the plurality of optical fibers.

16. The semiconductor package of claim 15, wherein the photonic integrated circuit includes a coupler, and
the coupler, the plurality of waveguides, and the plurality of optical fibers overlap each other in the second direction.

17. The semiconductor package of claim 15, wherein a top surface of the glass block is in contact with a bottom surface of the fastening structure.

18. The semiconductor package of claim 15, further comprising a mold layer disposed on a top surface of the photonic integrated circuit,
wherein the mold layer covers a side surface of the electronic integrated circuit and a side surface of the transfer structure, and
a top surface of the mold layer is placed at substantially the same level as a top surface of the transfer structure.

19. The semiconductor package of claim 15, wherein a side surface of each of the waveguides is aligned to a side surface of a corresponding one of the inner cores.

20. The semiconductor package of claim 15, wherein each of the plurality of waveguides includes at least one of silicon nitride or silicon oxide.
